(19) United States
(12) Patent Application Publication
(10) Pub. No.: US 2021/0090780 A1
(43) Pub. Date: Mar. 25, 2021

(54) COIL ELEMENT

(71) Applicant: TAIYO YUDEN CO., LTD., Tokyo (JP)

(72) Inventors: Motoki MATSUI, Tokyo (JP); Tomoo KASHIWA, Tokyo (JP)

(21) Appl. No.: 17/029,563

(22) Filed: Sep. 23, 2020

(30) Foreign Application Priority Data
Sep. 25, 2019 (JP) 2019-173646

(51) Int. Cl. H01F 27/255; H01F 27/29; H05K 1/18; H01F 41/02; H01F 41/04

(52) U.S. Cl. CPC H01F 27/255; H01F 27/292; H05K 2201/1003; H01F 41/0246; H01F 41/04; H05K 1/181

(57) ABSTRACT

A coil element according to one embodiment of the invention includes a magnetic base body including first metal magnetic particles that have a first average particle size and a first specific surface area, second metal magnetic particles that have a second average particle diameter smaller than the first average particle diameter and a second specific surface area, and a binder that holds the first metal magnetic particles and the second metal magnetic particles together. The coil element further includes a coil conductor provided in the magnetic base body. In one embodiment, a second surface roughness factor represented by a ratio of the second specific surface area to a second surface area estimated based on the second average particle diameter is greater than a first surface roughness factor represented by a ratio of the first specific surface area to a first surface area estimated based on the first average particle diameter.

### CROSS-REFERENCE TO RELATED APPLICATIONS

This application is based on and claims the benefit of priority from Japanese Patent Application Serial No. 2019-173646 (filed on Sep. 25, 2019), the contents of which are hereby incorporated by reference in its entirety.

### TECHNICAL FIELD

The present disclosure relates to a coil element.

### BACKGROUND

Various magnetic materials have been used in coils such as inductors. A coil element typically includes a magnetic base body made of a magnetic material, a coil conductor embedded in the magnetic base body, and external electrodes connected to ends of the coil conductor.

As the magnetic material for the magnetic base body, a composite magnetic material containing a plurality of metal magnetic particles and a resin binder is used. Such a magnetic base body is produced by, for example, making a mixed resin composition by mixing and kneading metal magnetic particles and resin, pouring the mixed resin composition into a mold, and applying pressure and heat to the composition in the mold. In this manufacturing process, the resin contained in the mixed resin composition is cured to form the binder. In this magnetic base body, metal magnetic particles are bound together by the binder.

Magnetic base bodies for coils are required to have a high magnetic permeability. Efforts have been made to improve the magnetic permeability of the magnetic base bodies. Japanese Patent Application Publication No. 2018-041955 discloses that a magnetic base body contains two or more types of metal magnetic particles having different average particle diameters. This can raise a filling factor (filling density) of the metal magnetic particles in the magnetic base body and accordingly improve the magnetic permeability of the magnetic base body. Japanese Patent Application Publication No. 2016-208002 discloses that a magnetic base body contains three types of metal magnetic particles having different average particle diameters from each other. This can raise the filling factor of the metal magnetic particles in the magnetic base body.

As described above, to increase the filling factor of the metal magnetic particles in the magnetic base body, two or three types of metal magnetic particles having different average particle diameters from each other have been included in the magnetic base body and thereby the magnetic permeability of the magnetic base body has been improved.

As the filling factor of the metal magnetic particles in the magnetic base body made of the composite magnetic material increases, the content ratio of the binder that binds the metal magnetic particles decreases. Therefore, in the conventional magnetic base body made of the composite magnetic material, there is a drawback that the mechanical strength is reduced when the filling factor of the metal magnetic particles is increased in order to improve the magnetic permeability.

### SUMMARY

One object of the present invention is to overcome at least a part of the above drawback. More specifically, the invention endeavors to provide a coil element including a magnetic base body with a high magnetic permeability and improved mechanical strength. Other objects of the invention will be made apparent through the entire description in the specification.

A coil element according to one aspect of the invention includes a magnetic base body including first metal magnetic particles that have a first average particle size and a first specific surface area, second metal magnetic particles that have a second average particle diameter smaller than the first average particle diameter and a second specific surface area, and a binder that holds the first metal magnetic particles and the second metal magnetic particles together. The coil element further includes a coil conductor provided in the magnetic base body. In one embodiment, a second surface roughness factor represented by a ratio of the second specific surface area to a second surface area estimated based on the second average particle diameter is greater than a first surface roughness factor represented by a ratio of the first specific surface area to a first surface area estimated based on the first average particle diameter.

In the coil element, a content ratio of the second metal magnetic particles in the magnetic base body may be 15 wt % or more.

In the coil element, a content ratio of the second metal magnetic particles in the magnetic base body may be 45 wt % or less.

In the coil element, the first metal magnetic particles may have a first oxide film on a surface thereof.

In the coil element, the first metal magnetic particles may have an insulating coating layer on a surface thereof.

In the coil element, the second metal magnetic particles may have a second oxide film on a surface thereof.

In the coil element, the magnetic base body may further include third metal magnetic particles that have a third average particle diameter smaller than the second average particle diameter and a third specific surface area.

In the coil element, a third surface roughness coefficient represented by a ratio of the third specific surface area to a third surface area estimated based on the third average particle diameter may be larger than the first surface roughness coefficient.

In the coil element, the third surface roughness coefficient may be larger than the second surface roughness coefficient.

According to another aspect of the invention, a circuit substrate includes any one of the above coil elements.

Yet another aspect of the invention relates to an electronic device comprising the above circuit substrate.

According to the aspect of the invention, it is possible to provide a coil element including a magnetic base body with a high magnetic permeability and improved mechanical strength.

### BRIEF DESCRIPTION OF THE DRAWINGS

FIG. 1 is a perspective view schematically showing a coil element according to one embodiment of the present invention.

FIG. 2 is a schematic sectional view of the coil element of FIG. 1 along the line I-I.

FIG. 3 is an enlarged sectional view of a magnetic base body of the coil element of FIG. 1.

FIG. 4 is a graph showing a particle size distribution of magnetic particles contained in the magnetic base body of the coil element of FIG. 1.

FIG. 5. schematically shows metal magnetic particles contained in the magnetic base body of the coil element of FIG. 1.

FIG. 6 is a perspective view showing a coil element according to another embodiment of the invention.

### DESCRIPTION OF THE EMBODIMENTS

Various embodiments of the present invention will be hereinafter described with reference to the accompanying drawings. Reference characters designating corresponding components are repeated as necessary throughout the drawings for the sake of consistency and clarity. It should be noted that components in the drawings are not necessarily drawn to scale for the sake of convenience of description.

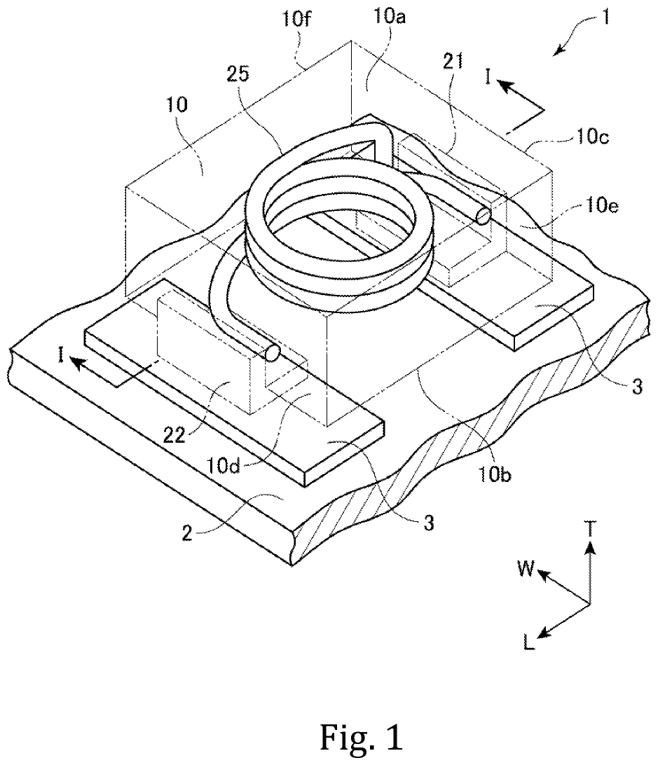

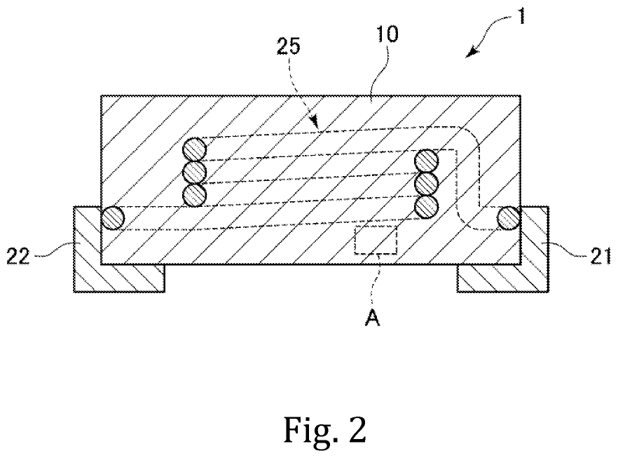

A coil element 1 according to one embodiment of the invention will be hereinafter described with reference to FIGS. 1 to 5. First, the coil element 1 is now briefly described with reference to FIGS. 1 and 2. FIG. 1 is a schematic perspective view of the coil element 1, and FIG. 2 schematically shows a section of the coil element 1 along the line I-I. As shown, the coil element 1 includes a base body 10, a coil conductor 25 provided in the base body 10, an external electrode 21 disposed on a surface of the base body 10, and an external electrode 22 disposed on a surface of the base body 10 at a position spaced from the external electrode 21.

In this specification, a “length” direction, a “width” direction, and a “thickness” direction of the coil element 1 correspond to the “L axis” direction, the “W axis” direction, and the “T axis” direction in FIG. 1, respectively, unless otherwise construed from the context. The “thickness” direction may be also referred to as a “height” direction.

The coil element 1 is mounted on a circuit substrate 2. The circuit substrate 2 has two land portions 3 provided thereon. The coil element 1 may be mounted on the circuit substrate 2 by soldering the external electrodes 21, 22 to the corresponding land portions 3 of the circuit substrate 2. The circuit substrate 2 can be installed in various electronic devices. Electronic devices in which the circuit substrate 2 may be installed include smartphones, tablets, game consoles, and various other electronic devices.

The coil element 1 is an example of coil to which the invention is applicable. The invention may be applied to inductors, transformers, filters, reactors, and various other coil elements. The invention may be also applied to coupled inductors, choke coils, and any other magnetically coupled coil elements. Applications of the coil element 1 are not limited to those explicitly described herein.

The base body 10 is made of a magnetic material and formed in a rectangular parallelepiped shape. In one embodiment of the invention, the base body 10 has a length (the dimension in the L axis direction) of 1.0 to 10.0 mm, a width (the dimension in the W axis direction) of 0.5 to 10.0 mm, and a thickness (the dimension in the T axis direction) of 0.8 to 5.0 mm. The dimensions of the base body 10 are not limited to those specified herein. The term “rectangular parallelepiped” or “rectangular parallelepiped shape” used herein is not intended to mean solely “rectangular parallelepiped” in a mathematically strict sense.

The base body 10 has a first principal surface 10a, a second principal surface 10b, a first end surface 10c, a second end surface 10d, a first side surface 10e, and a second side surface 10f. These six surfaces define the outer periphery of the base body 10. The first principal surface 10a and the second principal surface 10b are opposed to each other, the first end surface 10c and the second end surface 10d are opposed to each other, and the first side surface 10e and the second side surface 10f are opposed to each other.

As shown in FIG. 1, the first principal surface 10a lies on the top side in the magnetic base body 10, and therefore, the first principal surface 10a may be herein referred to as a “top surface.” Similarly, the second principal surface 10b may be referred to as a “bottom surface.” The coil element 1 is disposed such that the second principal surface 10b faces a circuit substrate 102, and therefore, the second principal surface 10b may be herein referred to as a “mounting surface.” The top-bottom direction of the coil element 1 refers to the top-bottom direction in FIG. 1.

In the embodiment shown, the external electrodes 21 are provided on the mounting surface 10b and the end surface 10c. The external electrodes 22 are provided on the mounting surface 10b and the end surface 10c of the magnetic base body 10. The shapes and positions of the external electrodes are not limited to the illustrated example. The external electrodes 21 and 22 are separated from each other in the length direction.

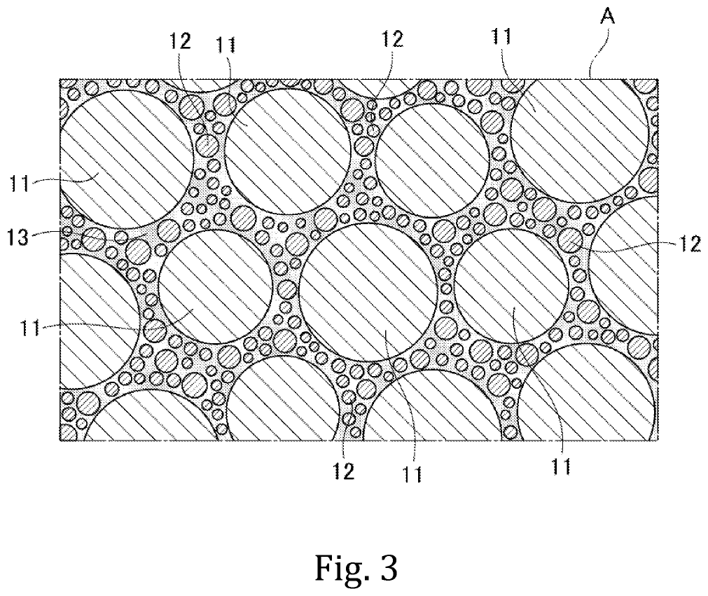

The magnetic base body 10 will be further described in detail with reference to FIG. 3. FIG. 3 is an enlarged schematic sectional view of the magnetic base body 10. FIG. 3 is an enlarged view of a region A of the magnetic base body 10 shown in FIG. 2. As shown in the drawing, the magnetic base body 10 includes a plurality of first metal magnetic particles 11, a plurality of second metal magnetic particles 12, and a binder 13. The plurality of first metal magnetic particles 11 and the plurality of second metal magnetic particles 12 are bound to each other with the binder 13. In other words, the magnetic base body 10 is formed of the plurality of first metal magnetic particles 11 and the plurality of second metal magnetic particles 12 bound by the binder 13. The region A may be any region in the magnetic base body 10.

The first metal magnetic particles 11 each has a larger particle diameter than the second metal magnetic particles 12. For example, the first metal magnetic particles 11 have a first average particle diameter in the range of 12 to 35 urn, and the second metal magnetic particles 12 have a second average particle diameter in the range of 1 to 8 μm. In one embodiment, the magnetic base body 10 may further include third metal magnetic particles (not shown) having a third average particle diameter smaller than the second average particle diameter. The third average particle diameter is, for example, 0.5 μm or smaller. The average particle diameter of the metal magnetic particles contained in the magnetic base body 10 is determined based on a photograph thereof. The magnetic base body 10 is cut along the thickness direction (T direction) to expose a section, and the section is scanned by a scanning electron microscope (SEM) to take the photograph at a 2000 to 5000-fold magnification. The size of each particle can be determined as the diameter of a circular cross section of the particle based on the SEM photograph of the cross section when the particle is considered as a sphere. An arithmetic average of the diameters of these individual spherical particles can be taken as the average particle diameter (D_{AVE}), and this value can be taken as the average particle diameter of the metal magnetic particles. When observing metal magnetic particles with a particle diameter smaller than 1 μm, a particle size distribution may be obtained based on an SEM photograph taken at a magnification of 5000 to 10000 times. When it is not necessary to distinguish between the first metal magnetic particles 11, the second metal magnetic particles 12, and the third metal magnetic particle, the first metal magnetic particle 11, the second metal magnetic particles 12, and the third metal magnetic particles contained in the magnetic base body 10 may be herein collectively referred to as “metal magnetic particles.”

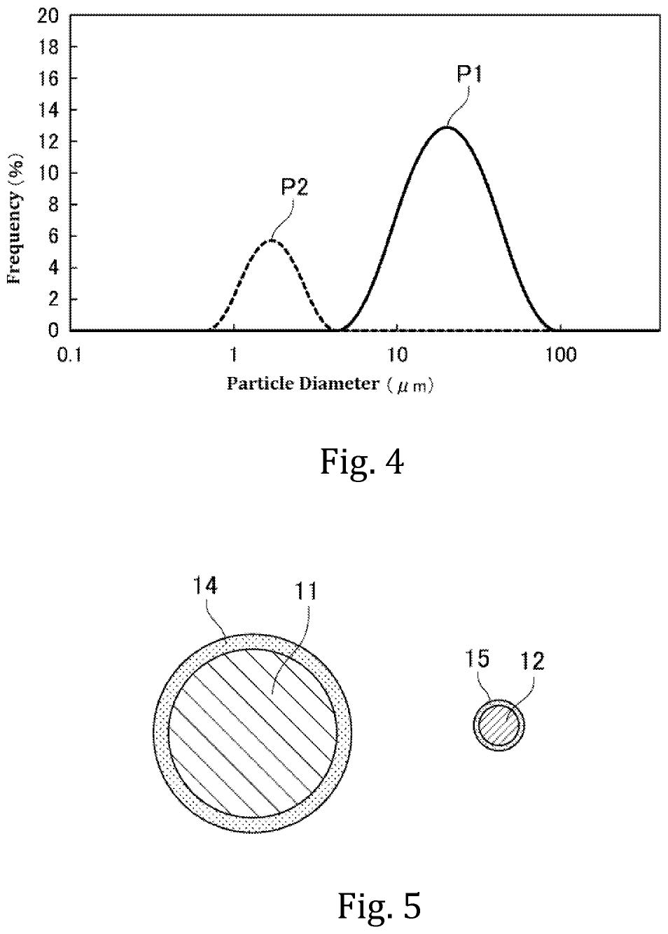

FIG. 4 is a graph showing an example of a particle size distribution of the metal magnetic particles contained in the magnetic base body 10. As shown, the particle size distribution graph includes two peaks: the first peak P1 and the second peak P2. In FIG. 4, the graph including the first peak P1 represents the particle size distribution of the first metal magnetic particles 11, and the graph including the second peak P2 represents the particle size distribution of the second metal magnetic particles 12. The first peak P1 is located within the range from 12 μm to 35 μm, and the second peak P2 is located within the range from 1 μm to 8 μm. As described above, the magnetic base body 10 in one embodiment is obtained by mixing the first metal magnetic particles 11 and the second metal magnetic particles 12 at a predetermined ratio. FIG. 4 shows the particle size distribution of these two types of metal magnetic particles mixed together. When the magnetic base body 10 contains the two types of the metal magnetic particles, two peaks appear in the graph of the particle size distribution of the metal magnetic particles contained in the magnetic base body 10. When the magnetic base body 10 further contains the third metal magnetic particles, the particle distribution graph includes a third peak indicating the particle size distribution of the third metal magnetic particles.

The first metal magnetic particles 11 and the second metal magnetic particles 12 may be made of various soft magnetic materials. The first metal magnetic particles 11 are mainly made of, for example, Fe. More specifically, the first metal magnetic particles are, for example, particles of (1) a metal such as Fe or Ni, (2) a crystalline alloy such as an Fe—Si—Cr alloy, an Fe—Si—Al alloy, or an Fe—Ni alloy, (3) an amorphous alloy such as an Fe—Si—Cr—B—C alloy or an Fe—Si—Cr—B alloy, or (4) a mixture thereof. The composition of the metal magnetic particles contained in the base body 10 is not limited to those described above. In the first metal magnetic particles, Fe accounts for 85 wt % or more. In this way, it is possible to obtain the magnetic base body 10 with an excellent magnetic permeability. The composition of the second metal magnetic particles 12 may be the same as or different from the composition of the first metal magnetic particles 11.

As shown in FIG. 5, an insulating film 14 may be provided on the surfaces of the first metal magnetic particles 11. The insulating film 14 is formed of glass, resin, or any other material having a high insulating property. The insulating film 14 is formed on the surfaces of the first metal magnetic particles 11 by mixing the first metal magnetic particles 11 and glass powder in a friction mixer, for example. The insulating film 14 made of the glass material is fixed to the surfaces of the first metal magnetic particles 11 through compression friction action in the friction mixer. The glass material may include ZnO and P20s. The insulating film 14 can be formed of various glass materials. The insulating film 14 may be formed of alumina powder, zirconia powder, or any other oxide powder having a high insulating property instead of or in addition to the glass powder. The thickness of the insulating film 14 is, for example, 100 nm or less. In the above described manner, the first metal magnetic particles 11 may have the insulating film 14 on the surface thereof. By forming the insulating film 14 on surfaces of the first metal magnetic particles 11, the surfaces of the first metal magnetic particles 11 can be made smooth. Thus, the first metal magnetic particles 11 having the insulating film 14 formed on the surfaces thereof may have a smaller specific surface area than the first metal magnetic particles 11 having no insulating film 14 thereon. The insulating film 14 may be an oxide film formed by oxidizing the first metal magnetic particles 11. By forming the insulating film 14 on the surfaces of the first metal magnetic particles 11, the specific surface area of the first metal magnetic particles 11 can be reduced.

An insulating film 15 may be provided on surfaces of the second metal magnetic particles 12. The insulating film 15 may be an oxide film formed by oxidizing the second metal magnetic particles 12. The thickness of the insulating film 15 is, for example, 20 nm or less. The insulating film 15 may be an oxide film formed on the surfaces of the second metal magnetic particles 12 by performing a heat treatment on the second metal magnetic particles 12 in the atmosphere. The insulating film 15 may be an oxide film containing oxides of Fe and any other element(s) contained in the second metal magnetic particles 12. Alternatively, the insulating film 15 may be an iron phosphate film formed on the surfaces of the second metal magnetic particles 12 by introducing the second metal magnetic particles 12 in phosphoric acid and stirring them. By forming the insulating film 15 on the surfaces of the second metal magnetic particles 12 in this manner, the surfaces of the second metal magnetic particles 12 can be roughened. The second metal magnetic particles 12 with the insulating film 15 formed thereon may have a larger specific surface area than the second metal magnetic particles 12 on which the insulating film 15 is not formed. By forming the insulating film 15 on the surfaces of the second metal magnetic particles 12, the specific surface area of the second metal magnetic particles 12 can be increased.

The binder 13 is, for example, a highly insulating thermosetting resin. An example of such a binder includes an epoxy resin, a polyimide resin, a polystyrene (PS) resin, a high-density polyethylene (HDPE) resin, a polyoxymethylene (POM) resin, a polycarbonate (PC) resin, a polyvinylidene fluoride (PVDF) resin, a phenolic resin, a polytetrafluoroethylene (PTFE) resin, and a polybenzoxazole (PBO) resin.

In one embodiment, the second metal magnetic particles 12 have a rougher surface than the first metal magnetic particles 11. In the specification, the surface roughness of a metal magnetic particle may be represented by a surface roughness factor which is a ratio of the specific surface area to the surface area of the metal magnetic particle. The surface roughness of a metal magnetic particle may be represented by a specific surface area per unit mass or per unit volume. However, as it is understood from the definition of the specific surface area, the specific surface area of a metal magnetic particle tends to increase as the particle diameter decreases. So in order to compare the surface roughness of the metal magnetic particles having different particle diameters, it is necessary to normalize the specific surface area with respect to the particle diameter. Here, a surface roughness factor, which is a ratio of the specific surface area to the surface area of a metal magnetic particle is used to compare the surface roughness of metal magnetic particles. For example, when the surface area of the first metal magnetic particle 11 is S1 and the specific surface area of the first metal magnetic particle 11 is A1, a first surface roughness factor F1, which is the surface roughness factor of the first metal magnetic particles 11, is represented by F1=A1/S1. Similarly, when the surface area of the second metal magnetic particle 12 is S2 and the specific surface area of the second metal magnetic particle 12 is A2, a second surface roughness factor F2, which is the surface roughness factor of the second metal magnetic particles 12, is represented by F2=A2/S2. The first surface roughness factor F1 and the second surface roughness factor F2 represent surface roughness normalized by the particle diameters of the first metal magnetic particle 11 and the second metal magnetic particle 12, respectively. Therefore, when the surface of the second metal magnetic particle 12 is rougher than the surface of the first metal magnetic particle 11, the first surface roughness factor F1 and the second surface roughness factor F2 satisfy F2>F1. When the insulating film 14 is formed on the surface of the first metal magnetic particle 11, the specific surface area A1 of the first metal magnetic particle 11 means the specific surface area of the first metal magnetic particle 11 with the insulating film 14 formed thereon. Similarly, when the insulating film 15 is formed on the surface of the second metal magnetic particle 12, the specific surface area A2 of the second metal magnetic particle 12 means the specific surface area of the second metal magnetic particle 12 with the insulating film 15 formed thereon. When the magnetic base body 10 contains the third metal magnetic particles, a third surface roughness factor F3 representing the surface roughness of the third metal magnetic particles may be larger than the first surface roughness factor F1. The third surface roughness factor F3 may be larger than the second surface roughness factor F2.

The surface area of a metal magnetic particle is calculated on the basis of the average particle diameter D_{AVE} of the particles on the assumption that the metal magnetic particles have spherical shapes. That is, a surface area S of metal magnetic particles having the average particle diameter D_{AVE} is represented by S=4π(D_{AVE}/2)². A surface area S1 of the first metal magnetic particle 11 is, for example, in the range of 4.0×10⁻¹⁰ to 5.0×10⁻⁹ m². A surface area S2 of the second metal magnetic particle 12 is, for example, in the range of 1.0×10⁻¹³ to 2.0×10¹⁰ m².

The specific surface area of a metal magnetic particle may be represented by a BET value (also referred to as a BET specific surface area). The BET values of the first metal magnetic particle 11 and the second metal magnetic particle 12 are obtained through a BET single-point method using Macsorb HM model-1208 manufactured by Mountech Co., Ltd. The BET value of the first metal magnetic particle 11 is, for example, in the range of 0.02 to 0.5 m²/g. The BET value of the second metal magnetic particle 12 is, for example, in the range of 0.3 to 0.5 m²/g. The range of the BET value of the first metal magnetic particle 11 and the range of the BET value of the second metal magnetic particle 12 partially overlap with each other, but a combination of the first metal magnetic particle 11 and the second metal magnetic particle 12 is selected such that the BET value of the second metal magnetic particle 12 becomes greater than the BET value of the first metal magnetic particle 11.

In one embodiment, the content ratio of the second metal magnetic particles 12 in the magnetic base body 10 is 15 wt % or more. In another embodiment, the content ratio of the second metal magnetic particles 12 in the magnetic base body 10 is 45 wt % or less. Since a density of the metal magnetic particles contained in the magnetic base body 10 is significantly higher than a density of other inclusions (for example, the binder 13), the content ratio (wt %) of the second metal magnetic particles 12 in the magnetic base body 10 can be approximately expressed as a ratio of the second metal magnetic particles 12 to the total mass 100 wt % of all the metal magnetic particles contained in the magnetic base body 10.

An example of manufacturing method of the coil element 1 according to one embodiment of the invention will now be described. The following describes a method of manufacturing the coil element 1 using a compression molding process. The method of manufacturing the coil element 1 using the compression molding process includes a molding step where a particle group including the metal magnetic particles 11 and the metal magnetic particles 12 and a resin are kneaded while being heated to produce a mixed resin composition and the mixed resin composition is compressed to form a molded body, and a heat treatment step where the molded body obtained by the molding step is heated. In the molding step, lubricant may be added in order to improve mobility of particles and a release agent may be also added in order to promote separation between the mold and the molded body.

In the molding step, the coil conductor 25 prepared in advance is disposed in a molding die, and the mixed resin composition is provided in the molding die in which the coil conductor 25 has been disposed. A compression pressure is then applied to the mixed resin composition in the molding die. In this way, a molded body including the coil conductor 25 thereinside is obtained. The molding step may be performed by warm molding or may be performed by cold molding. The compression pressure can be appropriately adjusted to obtain a desired filling factor.

After the molded body is obtained through the molding step, the manufacturing method proceeds to the heat treatment step. In the heat treatment step, heat treatment is performed on the molded body obtained in the molding step to produce the magnetic base body 10. By this heat treatment, the resin in the mixed resin composition is cured to become the binder 13, and the binder 13 bonds the first metal magnetic particles 11 and the second metal magnetic particles 12 together. The heat treatment is performed at a curing temperature of the resin, for example, at a temperature from 150° C. to 200° C. for a duration of 30 minutes to 4 hours. The heat treatment step may include degreasing of the molded body obtained in the molding step. Alternatively, degreasing may be independently performed from the heat treatment step.

Next, a conductor paste is applied to both end portions of the magnetic base body 10, which is produced in the above-described manner, to form the external electrode 21 and the external electrode 22. The external electrode 21 and the external electrode 22 are provided such that they are electrically coupled to respective ends of the coil conductor 25 provided in the magnetic base body 10. The external electrodes 21, 22 may include a plating layer. There may be two or more plating layers. The two plating layers may include an Ni plating layer and an Sn plating layer externally provided on the Ni plating layer. The coil element 1 is obtained, as described above.

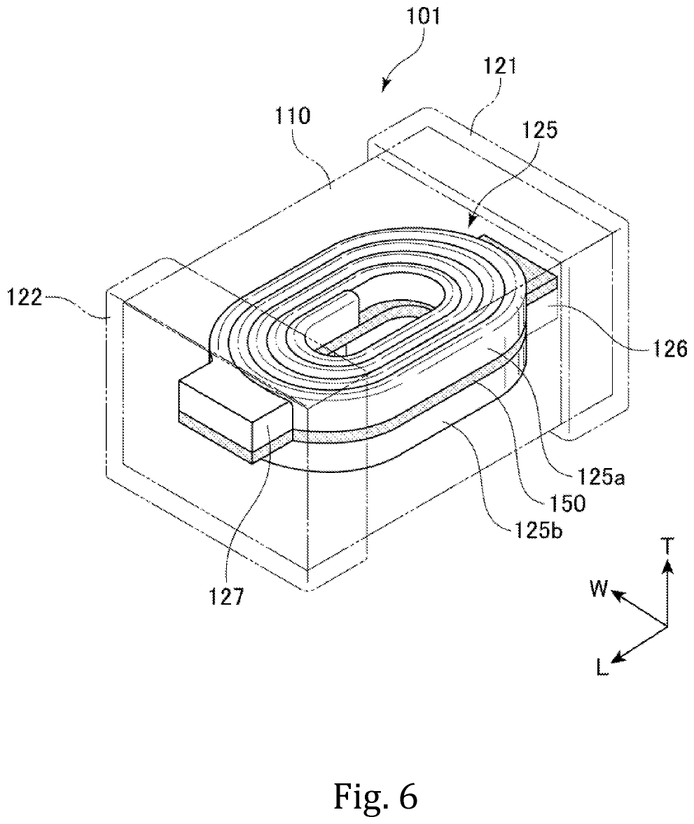

The following describes a coil element 101 according to another embodiment of the invention with reference to FIG. 6. The coil element 101 is a planar coil. As shown in FIG. 6, the coil element 101 according to the embodiment includes a magnetic base body 110, an insulating plate 150 provided in the magnetic base body 110, a coil conductor 125 provided on upper and lower surfaces of the insulating plate 150 in the magnetic base 110, an external electrode 121 provided on the magnetic base body 110, and an external electrode 122 provided on the magnetic base body 110 at a position apart from the external electrode 121.

In the embodiment, similarly to the above-described magnetic base body 10, the magnetic base body 110 includes the plurality of first metal magnetic particles 11, the plurality of second metal magnetic particles 12, and the binder 13. The insulating plate 150 is made of an insulating material and has a plate-like shape. The insulating material used for the insulating plate 150 may be magnetic. The magnetic material used for the insulating plate 150 is, for example, a composite magnetic material containing a binder and metal magnetic particles.

In the embodiment shown, the coil conductor 125 includes a coil conductor 125a formed on the upper surface of the insulating plate 150 and the coil conductor 125b formed on the lower surface of the insulating plate 150. The coil conductor 125a and the coil conductor 125b are connected by a via (not shown). The coil conductor 125a is formed in a predetermined pattern on the upper surface of the insulating plate 150, and the coil conductor 125b is formed in a predetermined pattern on the lower surface of the insulating plate 150. An insulating film may be provided on surfaces of the coil conductors 225a and 225b. The coil conductor 125 can be provided in various shapes. When seen from above, the coil conductor 125 has, for example, a spiral shape, a meander shape, a linear shape or a combined shape of these.

In one embodiment of the invention, the insulating plate 150 has a larger resistance than the magnetic base body 110. Thus, even when the insulating plate 150 has a small thickness, electric insulation between the coil conductor 125a and the coil conductor 125b can be ensured.

A lead conductor 127 is provided on one end of the coil conductor 125a and a lead conductor 126 is provided on one end of the coil conductor 125b. In this manner, the coil conductor 125 is electrically coupled to the external electrode 121 via the lead conductor 126 and is electrically coupled to the external electrode 122 via the lead conductor 127.

Next, a description is given of an example of a manufacturing method of the coil element 101. To start with, an insulating plate made of a magnetic material and shaped like a plate is prepared. Photoresist is applied to the upper and the lower surfaces of the insulating plate, and then conductor patterns are transferred onto the upper and lower surfaces of the insulating plate by exposure, and development is performed. As a result, a resist having an opening pattern for forming a coil conductor is formed respectively on the upper and lower surfaces of the insulating plate. For example, the conductor pattern formed on the upper surface of the insulating plate corresponds to the coil conductor 125a described above, and the conductor pattern formed on the lower surface of the insulating plate corresponds to the coil conductor 125b described above. A through hole for providing the via is formed in the insulating plate.

Subsequently, plating is performed to fill each of the opening patterns with a conductive metal. Etching is then performed to remove the resists from the insulating plate and the coil conductors are formed on the upper and lower surfaces of the insulating plate. Further, by filling the through-hole in the insulating plate with a conductive metal, the via that connects the coil conductor 125a and the coil conductor 125b is formed.

A magnetic base body is subsequently formed on both surfaces of the insulating plate where the coil conductors have formed thereon. This magnetic base body corresponds to the magnetic base body 110 described above. To form the magnetic base body, a magnetic sheet is first fabricated. The magnetic sheet is fabricated by mixing and kneading a group of the metal magnetic particles 11 and the metal magnetic particles 12 and a resin while heating them to form a mixed resin composition, pouring the mixed resin composition into a sheet-shaped mold and then cooling the mixed resin composition in the sheet-shaped mold. In the above manner, a pair of magnetic sheets are fabricated. Next, the above-described coil conductors are placed between the magnetic sheets and pressure is applied to them while they are heated. In this way, a laminated body is fabricated. Next, the laminated body is subjected to heat treatment at the curing temperature of the resin, for example, at a temperature of 150° C. to 200° C. for a duration of 30 minutes to four hours. In this way, the magnetic base body 110 having the coil conductor 125 therein can be obtained. In the magnetic base body 110, the resin in the mixed resin composition is cured and serves as the binder 13. The first metal magnetic particles 11 and the second metal magnetic particles 12 are bound to each other with the binder 13. External electrodes 121, 122 are provided on the external surface of the magnetic base body at predetermined positions. In this manner, the coil element 101 is fabricated.

### Example

First, Fe—Si—B—C amorphous alloy powder having an average particle diameter of 25 μm was prepared as the first metal magnetic particles 11, and carbonyl iron powder having an average particle diameter of 5 μm was prepared as the second metal magnetic particles 12. These two kinds of metal magnetic powders were mixed in the ratios shown in Table 1 to obtain mixed powders. Table 1 shows the content ratios of the first metal magnetic particles 11 and the second metal magnetic particles 12 to the total mass 100 wt % of the first metal magnetic particles 11 and the second metal magnetic particles 12. Further, the BET value was measured respectively for the first metal magnetic particles 11 and the second metal magnetic particles 12 using Macsorb HM model-1208 manufactured by Mountech Co., Ltd., and the surface roughness factors thereof were calculated. As a result, the surface roughness factor F1 of the first metal magnetic particles 11 was 5.4×10⁷, and the surface roughness factor F2 of the second metal magnetic particles 12 was 8.3×10⁹.

Next, each of the mixed powders was kneaded with an epoxy resin to obtain a mixed resin composition. The mixed resin compositions were heated at 170° C. for 10 minutes while applying a molding pressure of 15 MPa to obtain rectangular parallelepiped magnetic substrate samples (Samples 1 to 8). Each of Samples 1 to 8 was subjected to a bending strength test according to JIS K6911 to measure the bending strength, and the magnetic permeability (μ) was measured using a BH analyzer. In addition, a filling factor was measured for the samples No. 1 to No. 8. Each sample was cut along the thickness direction to expose a cross section, and the filling factor was defined as a ratio of the area occupied by the metal magnetic particles to the total viewing field area of the cross section. If the content ratio of the second metal magnetic particles 12 exceeds 50 wt %, the mixed resin composition loses fluidity and it becomes difficult to prepare a sample in the compression molding process. Therefore the upper limit of the content ratio of the second metal magnetic particles 12 was set to 50 wt %. The measurement result is shown in Table 1 below.

TABLE 1

| | First Metal | Second Metal | Bending | Filling | |
|---|---|---|---|---|---|
| | Magnetic | Magnetic | Strength | Factor | |
| Sample No. | Ptcl. (wt %) | Ptcl. (wt %) | (Mpa) | (%) | μ |
| 1 | 95 | 5 | 22 | 79.5 | 29 |
| (Comp. Ex.) | | | | | |
| 2 | 90 | 10 | 40 | 80.1 | 29.5 |
| (Comp. Ex.) | | | | | |
| 3 | 85 | 15 | 78 | 81.4 | 31.2 |
| (Example) | | | | | |
| 4 | 80 | 20 | 86 | 81.7 | 31.5 |
| (Example) | | | | | |
| 5 | 70 | 30 | 100 | 81.8 | 31.6 |
| (Example) | | | | | |
| 6 | 60 | 40 | 111 | 81.5 | 31.3 |
| (Example) | | | | | |
| 7 | 55 | 45 | 116 | 81.2 | 31.1 |
| (Example) | | | | | |
| 8 | 50 | 50 | 102 | 80.3 | 30.0 |
| (Example) | | | | | |

Since the magnetic base body contains the particles 12, the filling factor of the metal magnetic particles in the magnetic base body can be increased. Therefore, the magnetic base body 10 has a high magnetic permeability. Moreover, since the second surface roughness factor F2 is larger than the first surface roughness factor F1, the second metal magnetic particles 12 have rough surfaces. As a result, the contact area between the second metal magnetic particles 12 and the binder 13 can be increased, so that the second metal magnetic particles 12 and the binder 13 form a solid skeleton structure. The first metal magnetic particles 11 are held by the skeleton structure formed by the second metal magnetic particles 12 and the binder 13. By strengthening the bond between the second metal magnetic particles 12 and the binder 13, the mechanical strength of the magnetic base body 10 can be improved even when the filling factor of the metal magnetic particles is high.

In the above-described embodiment, since the third surface roughness factor F3 is larger than the first surface roughness factor F1, the third metal magnetic particles also form a part of the solid skeleton structure formed by the second metal magnetic particles 12 and the binder 13. When the third surface roughness factor F3 is larger than the second surface roughness factor F2, the third metal magnetic particles are bonded to the binder 13 more firmly than the second metal magnetic particles 12, so that the mechanical strength of the magnetic base body 10 can be further enhanced.

According to the above embodiment, the content ratio of the second metal magnetic particles is 15 wt % or more, so that the mechanical strength of the magnetic base body 10 can be further improved.

According to the above embodiment, since the content ratio of the second metal magnetic particles is 45 wt % or less, a high magnetic permeability of the magnetic base body 10 can be maintained by the first metal magnetic particles 11 contained in the magnetic substrate 10.

The dimensions, materials, and arrangements of the constituent elements described herein are not limited to those explicitly described for the embodiments, and these constituent elements can be modified to have any dimensions, materials, and arrangements within the scope of the present invention. Furthermore, constituent elements not explicitly described herein can also be added to the described embodiments, and it is also possible to omit some of the constituent elements described for the embodiments.

What is claimed is:

1. A coil element comprising:
a magnetic base body including first metal magnetic particles that have a first average particle diameter and a first specific surface area, second metal magnetic particles that have a second average particle diameter smaller than the first average particle diameter and a second specific surface area, and a binder that holds the first metal magnetic particles and the second metal magnetic particles together; and
a coil conductor provided in the magnetic base body,
wherein a second surface roughness factor represented by a ratio of the second specific surface area to a second surface area estimated based on the second average particle diameter is greater than a first surface roughness factor represented by a ratio of the first specific surface area to a first surface area estimated based on the first average particle diameter.

2. The coil element of claim 1, wherein a content ratio of the second metal magnetic particles in the magnetic base body is 15 wt % or more.

3. The coil element of claim 1, wherein a content ratio of the second metal magnetic particles in the magnetic base body is 45 wt % or less.

4. The coil element of claim 1, wherein the first metal magnetic particles have a first oxide film on a surface thereof.

5. The coil element of claim 1, wherein the first metal magnetic particles have an insulating coating layer on a surface thereof.

6. The coil element of claim 1, wherein the second metal magnetic particles have a second oxide film on a surface thereof.

7. The coil element of claim 1, wherein the magnetic base body further includes third metal magnetic particles that have a third average particle diameter smaller than the second average particle diameter and a third specific surface area.

8. The coil element of claim 7, wherein a third surface roughness factor represented by a ratio of the third specific surface area to a third surface area estimated based on the third average particle diameter is larger than the first surface roughness factor.

9. The coil element of claim 7, the third surface roughness factor is larger than the second surface roughness factor.

10. A circuit substrate comprising the coil element of claim 1.

11. An electronic device comprising the circuit substrate according to claim 10.
